(19) United States
(12) Patent Application Publication
(10) Pub. No.: US 2011/0242837 A1
(43) Pub. Date: Oct. 6, 2011

(54) DEVICE FOR MIXING LIGHT

(75) Inventors: Hugo J. Cornelissen, Waalre (NL); Dirk K. G. De Boer, Den Bosch (NL)

(73) Assignee: KONINKLIJKE PHILIPS ELECTRONICS N.V., EINDHOVEN (NL)

(21) Appl. No.: 13/139,548

(22) PCT Filed: Dec. 8, 2009
(86) PCT No.: PCT/IB2009/055584

§ 371 Date: Jun. 14, 2011

(30) Foreign Application Priority Data
Dec. 16, 2008 (EP) 08171722.5

(51) Int. Cl. H01L 33/02; G02B 6/00

(52) U.S. Cl. 362/555; 362/551

(57) ABSTRACT

The present invention relates to a device for mixing light. More specifically, the invention relates to a device for mixing light 100 comprising at least two light sources wherein a first light source 101 emit light of a first wavelength and a second light source 102 emit light of a second wavelength, and further comprising at least one light guide 103 which has a diffraction grating 104 for outcoupling of light and a facet for each of the at least two light sources for incoupling of light, whereby a first facet 105 is adapted to couple light of the first wavelength into the at least one light guide 103, and a second facet 106 is adapted to couple light of the second wavelength into the at least one light guide 103.

### FIELD OF THE INVENTION

The present invention relates to a device for mixing light.

### BACKGROUND OF THE INVENTION

There are various ways to mix light from light sources of different colors, like red (R), green (G) and blue (B) LEDs, to make white light or light of a desired color. Light guides are used for mixing and guiding light emitted by light sources in various lightning solutions. By having a surface relief structure, like a diffraction grating, on the surface of the light guide the light transported and reflected in the light guide structure may be extracted at the surface to obtain an illumination pattern. The efficiency of the diffraction for the extracted light, i.e. outcoupled light, of the different colors determines the perceived quality or color of the mixed light. The diffraction efficiency is a value that expresses the extent to which energy can be obtained from diffracted light with respect to the energy of the incident light.

The diffraction angles of the light diffracted by the diffraction grating are determined by the grating law; mλ/Λ=n₀ sin θₒᵤₜ−n_{g} sin θ_{g}, where m is the diffraction order, λ the wavelength of the light, Λ the grating period, n_{g} and n₀ the refractive indices of the light guide and the outside medium, respectively, and θ_{g} and θₒᵤₜ the angles with respect to the surface normal of the light inside and outside the light guide, respectively. For a total internal reflection of the light to occur, i.e. when the 0^{th} order reflected beam is reflected by total internal reflection, the condition; θ_{c}<θ_{g}<90°, should be fulfilled, where θ_{c}=a sin (n₀/n_{g}) is the critical angle for total internal reflection.

US-20050259939 discloses a light guide which includes ultra thin light guide layers and multi layer applications. The light guide element has a thickness similar to the height of the light source. Further it is generally submitted that where the light guide element includes multiple light guide layers the incoupling may vary among the layers.

With conventional devices for mixing light there is a risk for too low diffraction efficiency as a result of reflection losses in the light guide, or imbalance in diffraction efficiencies between light of different wavelengths, affecting the quality of the outcoupled light which does not correspond to the desired color.

### SUMMARY OF THE INVENTION

In view of the above, it would be desirable to provide a device for mixing light with improved diffraction efficiency.

According to an aspect of the present invention, there is provided a device for mixing light comprising at least two light sources wherein a first light source emits light of a first wavelength and a second light source emits light of a second wavelength. The device for mixing light further comprises at least one light guide which has a diffraction grating for outcoupling of light and a facet for each of the at least two light sources for incoupling of light, whereby a first facet is adapted to couple light of the first wavelength into the at least one light guide, and a second facet is adapted to couple light of the second wavelength into the at least one light guide. Light of the different wavelengths enters the light guide through separate facets, after which multiple reflections occur in the light guide. By having individual light incoupling facets for each wavelength the reflection conditions can be optimized, for example, minimize reflection losses, in the light guide for each wavelength thus an improved diffraction efficiency is obtained with the device for mixing light. One or more light guides can be used, each having a light incoupling facet for each wavelength. The outcoupling or extraction of light is provided by the diffraction grating which diffracts the light at the surface of the light guide to the surrounding medium, for example air.

In an embodiment of the present invention the first and second facet is mounted in an angle in relation to the at least one light guide, wherein a first angle of the first facet may correspond to an angle for total internal reflection of the first wavelength in the at least one light guide, and a second angle of the second facet may correspond to an angle for total internal reflection of the second wavelength in the at least one light guide. Each facet has an angle in relation to, for example, the plane in which the light guide extends, a plane which may be parallel to the light extraction surface and/or diffraction grating. The angle of the facet is determined by the total internal reflection (TIR) condition in the light guide for the particular wavelength of the light entering the facet. As light enters the light guide in the TIR condition it allows the full amount of light to be extracted with the diffraction gratings. In case of arbitrary (non-TIR) angle incoupling of light at the facet, a non-diffracted order of the light is present, that is the zero'th order, and this light will not propagate in the light guide and will be lost. Reflection losses, such as Fresnel reflection losses, can be minimized according to the present invention.

In an embodiment of the present invention the first and second light source may emit light into separate light guides, such that a first light guide direct light of the first wavelength and a second light guide direct light of the second wavelength. By having separate light guides for each light source and wavelength the light guide parameters may be adjusted for each of the wavelengths, and an overlapping range of maximum diffraction efficiency for each wavelength may be ensured to provide homogeneous light of the desired color. The overlapping range may be construed as a range of diffraction angles, in which range the maximum diffraction efficiency is achieved for each wavelength.

In an embodiment of the present invention the first and second light guides may extend in two parallel planes, separated by an air spacing. By having parallel planes a compact design of the light mixing device is provided, and the air spacing between the light guides ensures that the TIR condition can be fulfilled. Another medium besides air may be used, provided that the refractive index of the medium allows TIR in the light guide. In an embodiment of the present invention the device for mixing light may further comprise a third light source, wherein the first, second and third light source each emit wavelengths corresponding to any of red, green or blue light. Accordingly, the first light source may emit red, green or blue light, and likewise for the second and third light source. Additional light sources may be used, each with their specific wavelengths.

In an embodiment of the present invention the device for mixing light may comprise a reflector positioned parallel to the at least one light guide. By having a reflector such as a mirror the light can be reflected in one desired direction only. More than one reflector may be used.

In an embodiment of the present invention three light guides may extend in three planes parallel to each other, where the reflector may be closest to the third light guide, and the third light guide directs red light, the second light guide directs green light, and the first light guide directs blue light, wherein the second light guide is positioned between the first and third light guide. The light guides extending in three parallel planes should be construed as the surface of light extraction of the first light guide is parallel to the surface of light extraction of the second and third light guides. By having such order of the light guides an efficient outcoupling of light is obtained to achieve light extraction of the desired color. The efficiency of light outcoupling may be construed as the diffraction efficiency.

In an embodiment of the present invention the thickness of the light guide, a diffraction grating period, or diffraction grating depth or any combination thereof may be adapted such that the efficiency of light outcoupling is within a range for all wavelengths. By adapting the mentioned parameters the same outcoupling efficiency can be achieved for all wavelengths for producing light of the desired color.

In an embodiment of the present invention the light of the first wavelength may be collimated to enter the first facet parallel to the surface normal of the first facet, and the light of the second wavelength may be collimated to enter the second facet parallel to the surface normal of the second facet. By collimating the light to enter the facet parallel to the normal of the facet surface reflection losses will be minimized. If light enters the light guide in the TIR condition the full amount of incident light may be extracted with the diffraction gratings. Due to such incoupling of light for each wavelength the reflection losses may be minimized for each of these wavelengths.

In an embodiment of the present invention the diffraction grating of the first light guide may define an offset angle with respect to the diffraction grating of the second light guide. By having an off-set angle between the gratings, and the light guides having similar configurations, the light sources can be displaced in respect to each other, for providing a more compact design and/or avoiding light source interference.

In an embodiment of the present invention the diffraction grating may cover at least one light outcoupling surface of the at least one light guide. The grating may be provided on one, two or more sides of the light guide intended for light extraction. More than one grating may provide a more efficient light outcoupling.

In an embodiment of the present invention the at least two light sources are LEDs. Any other light source, e.g. a bulb may be used.

In an embodiment of the present invention the light outcoupled by the diffraction grating is white. If the light sources emit R, G, and B light, the mixed light emitted from the light guide is white light, as the diffraction efficiency of each color are within a range, i.e. overlap at a desired angular range of light diffraction. Light of any desired color may be extracted by the diffraction grating.

This and other aspect of the invention will be apparent from and elucidated with reference to the embodiments described hereinafter. Generally, all terms used in the claims are to be interpreted according to their ordinary meaning in the technical field, unless explicitly defined otherwise herein. All references to “a/an/the/said [element, device, component, means, step, etc]” are to be interpreted openly as referring to at least one instance of said element, device, component, means, step, etc., unless explicitly stated otherwise.

### BRIEF DESCRIPTION OF THE DRAWINGS

Other features and advantages of the present invention will become apparent from the following detailed description of a presently preferred embodiment, with reference to the accompanying drawings, in which:

FIG. 1 shows an example of a device for mixing light.

FIG. 2 shows another example of a device for mixing light.

FIG. 3 shows a portion of the device for mixing light according to the first embodiment.

FIG. 4 shows a portion of the device for mixing light according to the second embodiment.

### DETAILED DESCRIPTION OF THE INVENTION

The present invention will now be described more fully hereinafter with reference to the accompanying drawings, in which certain embodiments of the invention are shown. This invention may, however, be embodied in many different forms and should not be construed as limited to the embodiments set forth herein; rather, these embodiments are provided by way of example so that this disclosure will be thorough and complete, and will fully convey the scope of the invention to those skilled in the art. Like numbers refer to like elements throughout.

In general, the present invention relates to a device for mixing light.

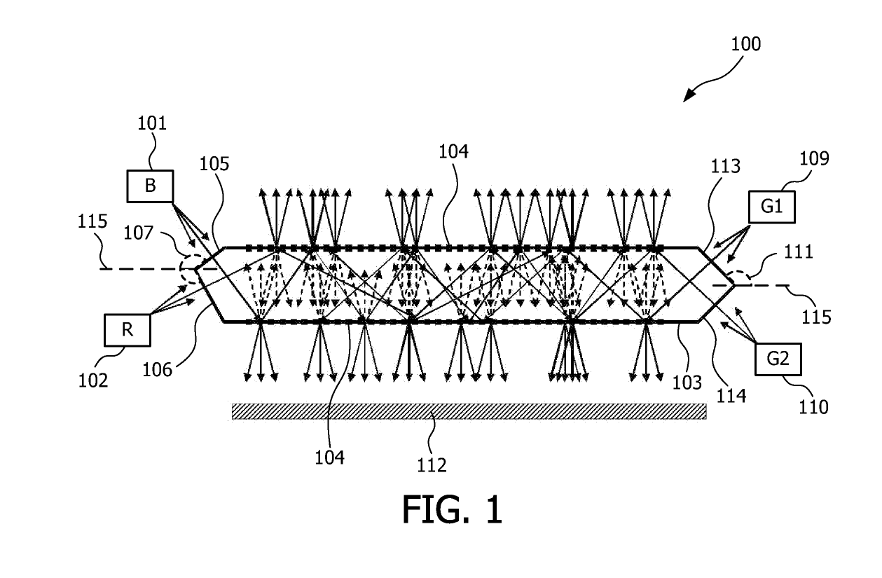

A schematic drawing in one embodiment of the present invention is shown in FIG. 1, showing a device for mixing light 100 with a light guide 103 having a diffraction grating 104 on its surface for outcoupling of light, and light sources 101, 102, 109, 110 emitting light of different wavelengths. A first light source 101 emit light of a specific wavelength and correspondingly for the remainder of the light sources. The light guide 103 comprise facets 105, 106, 113, 114 corresponding to each of the wavelengths of the light emitted by the light sources 101, 102, 109, 110. I.e. a first facet 105 couples the light of the first light source 101 into the light guide 103, whereupon the light is reflected repeatedly inside the light guide 103. Likewise, a second facet 106 directs the light of a second light source 102 into the light guide 103, and subsequent reflections of the light from the multiple light sources will occur in the light guide 103. The diffraction grating 104 of the light guide 103 will diffract the light of light sources 101, 102, 109, 110, each with their specific wavelengths, to the medium outside the light guide 103. Each reflection in the light guide 103 may lead to an unwanted loss of light which lowers the outcoupling efficiency to the outside medium. The reflection characteristics and loss of light depends on the wavelength of the light, hence by having individual light incoupling facets 105, 106, 113, 114 the losses can be avoided for each of the light sources 101, 102, 109, 110.

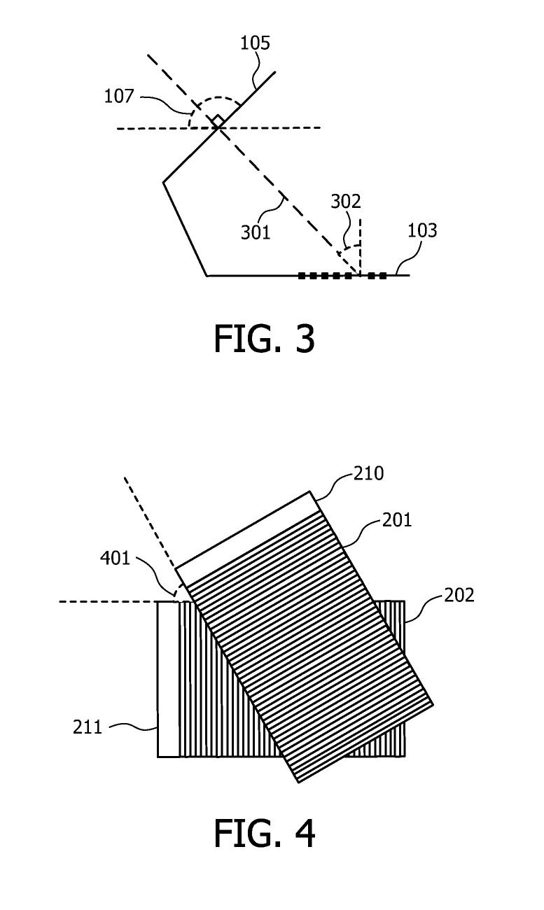

The first facet 105 has an angle, referred to as a first angle 107, in relation to a plane 115 of the light guide 103, which plane is parallel the to the diffraction grating 104 which defines the plane of light extraction. The first facet 105 couples light from the first light source 101, emitting light of a first wavelength, into the light guide 103. The first angle 107 corresponds to an angle for total internal reflection (TIR) of the first wavelength in the light guide 103. An angle for TIR should be construed as an angle θ_{g} that fulfills the condition; θ_{c}<θ_{g}<90°, where θ_{c} is the critical angle at which the TIR condition starts in the angular range for the specific wavelength, hence, TIR occurs for the range of angles between θ_{c} and 90°. FIG. 3 shows an example according to the embodiment in FIG. 1, where the first angle 107 corresponds to an angle 302 (θ_{g}) for TIR in the light guide 103 such that a principal direction 301, parallel to the surface normal of the first facet 105, is parallel to the direction described by the angle 302 (θ_{g}) for TIR. Likewise, the second facet 106 has an angle, referred to as a second angle 108, in relation to the plane 115 of the light guide 103, and the second facet 106 couples light from the second light source 102, emitting light of a second wavelength, into the light guide 103. The second angle 108 corresponds to an angle for TIR of the second wavelength in the light guide 103, which may be different from the first angle 107 if the light sources 101 and 102 emit light of different wavelengths. The TIR condition can thus be fulfilled for both light sources due to the individual configurations of the facet angles. In FIG. 1 more light sources are shown, 109 and 110, with their corresponding facets, 113 and 114, respectively for incoupling of light at the angle 111, which in the exemplifying embodiment are identical for both light sources illustrating that the wavelength is the same for light sources 109 and 110. More light sources can be used with different wavelengths and individual facets at angles corresponding to the TIR condition for these wavelengths in the light guide 103. A result from that the light enters the light guide 103 in the TIR condition is that the full amount of light can be extracted with the diffraction grating 104. This is because multiple bounces or interactions with the diffraction grating 104 occur. If the diffraction efficiency is not at maximum for a single interaction, and it never is, then the multiple interactions ensure that a high diffraction efficiency is achieved after all.

For the TIR condition to be fulfilled, it is advantageous to have a small θ_{c} and hence a large n_{g}. In practice, polycarbonate with n_{g}=1.58 is a suitable material, but also PMMA (n_{g}=1.49) or glass (n_{g}=1.5) may be used. In such light guide configuration the angular luminance distributions are preserved.

In FIG. 1 the light of the first wavelength emitted by the first light source 101 is collimated to enter the first facet 105 in a direction parallel to the surface normal of the first facet 105. Accordingly, the direction of light entry is parallel to the direction described by the angle 302 (θ_{g}), illustrated in FIG. 3 for the TIR condition. Each of the light sources 101, 102, 109 and 110, emit light in a direction parallel to their respective light incoupling facets, 105, 106, 113, and 114, and the TIR condition can be fulfilled for each of them to achieve the necessary outcoupling efficiency.

The light sources may have wavelengths corresponding to red (R), blue (B), and green (G) light. The light sources in the embodiment in FIG. 1 are denoted according this implementation, where the first light source 101 emit blue light, the second light source 102 emit red light and the third and forth light source, 109 and 110, both emit green light. Hence, the red, green and blue light is reflected by multiple TIR reflections in the light guide 103 and the light is outcoupled by the diffraction grating 104 to produce white light. The light sources may be light emitting diodes (LEDs) or any other light source suitable to emit light into the light guide 103.

The outcoupling efficiencies of the three colors vary, resulting in a preferred outcoupling for short wavelengths, which effect will be enhanced because of the larger number of bounces in the light guide 103 at shorter wavelengths. As will be discussed in connection with the next embodiment, in principle there are several ways to change the outcoupling efficiency, for example by varying the period, depth and shape of the diffraction grating 104, the coverage of the diffraction grating 104, or the thickness of the light guide 103 or any other parameter affecting the outcoupling efficiency. Outcoupling efficiency may be construed as diffraction efficiency. The thickness of the light guide 103 may be optimized to achieve maximum diffraction efficiency, for example a light guide thickness of 250 nm may lead to a maximum diffraction efficiency for all colors. A second-order diffraction may occur for blue light. With a proper design of the shape of the grating the intensity of this second order may be minimized.

A reflector 112 may be placed parallel to the light guide 103. Light emitted in the direction of the reflector 112 will be reflected in the opposite direction and all of the light extracted at the diffraction grating 104 will be directed to the opposite side of the light guide 103 in relation to the reflector 112. The reflector 112 may be placed along other directions relative to the light guide 103 depending on the desired direction for light emission.

The diffraction grating 104 may cover both sides of the light guide 103, as exemplified in FIG. 1. Only one diffraction grating 104, or several diffraction gratings, may be used. The diffraction grating can be embossed onto the light guide with a relatively low-cost embossing process.

It is advantageous to have a symmetric distribution of the outcoupled light around θₒᵤₜ=0°. Illustrating examples for facet angle configurations are presented below for red (R), green (G), and blue (B) LEDs, emitting in narrow wavelength ranges around λ=630, 530 and 470 nm, respectively. A high outcoupling efficiency for the −1^{st} order (m=−1) is desired. If the grating period is in the range 440<Λ<470 nm, the condition θ_{c}<θ_{g}<90° may be fulfilled for all colors. In that case, the outcoupled beam is narrow, for example: −2.5°<θₒᵤₜ<2.5°. The incident beams are collimated by collimation optics before directed to the incoupling facets, in this case the collimation may be ±5.5° for R, ±3.7° for G and ±3.3° for B, which could be achieved by using standard collimation optics, like lenses and (parabolic) mirrors. The facet angles with respect to the top and bottom surfaces of the light guide are in this case 62° for R, 48° for G and 41° for B in order to have light entering the light guide in the TIR condition. A wider beam is possible to achieve if an off-normal angular distribution is allowed. For example, a grating a divergence of ±5.0° can be obtained in the range 11°<θₒᵤₜ<21°, using an input divergence of ±9.7° for R, ±7.3° for G and ±6.7° for B, and with a grating with Λ=580 nm. In this case, the facet angles with respect to the top and bottom surfaces of the light guide are 60° for R, 49° for G and 44° for B. If desired, a prismatic redirection foil could be used to obtain a more symmetric distribution. Furthermore, only the angular distribution of light in the plane of drawing was considered in the above example. The divergence in the direction perpendicular to that may be essentially equal to the divergence of the incident beam.

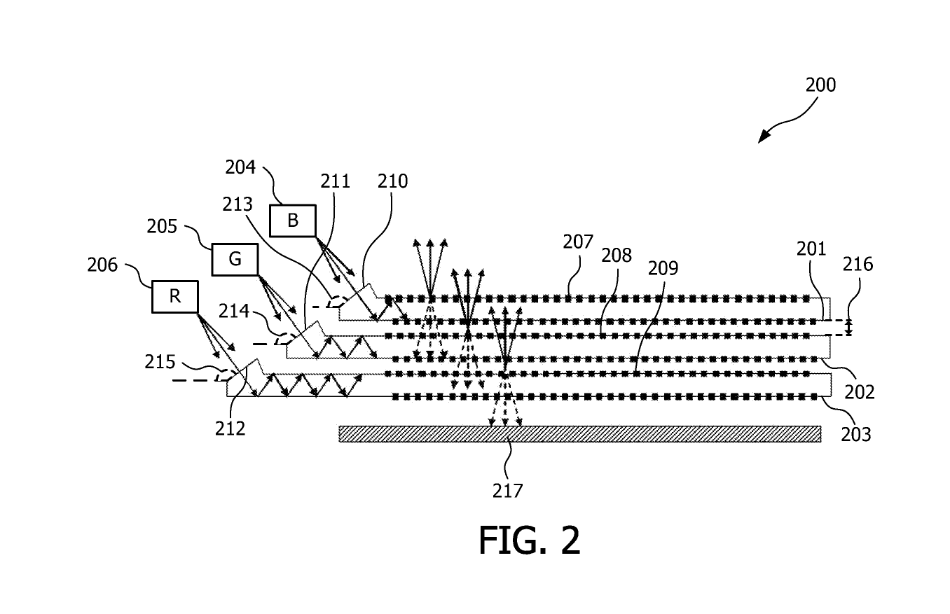

A schematic drawing of a second embodiment of the present invention is shown in FIG. 2. In this exemplifying embodiment of the device for mixing light 200 the angular output range may be larger than in the embodiment shown in FIG. 1, and a second-order diffraction in the blue can be avoided. In FIG. 2 the first and second light source, 204 and 205, respectively emit light into separate light guides, such that a first light guide 201 direct light of the first wavelength and a second light guide 202 direct light of the second wavelength. A third light source 206 is also presented and its respective light guide 203. The facets 210, 211, and 212 couple the light of the light sources 204, 205, and 206, into the light guides 201, 202, and 203, respectively. As in the embodiment described in FIG. 1 each specific facet has an angle corresponding to an angle for TIR in the light guide of the light entering that specific facet. The facet 210 has an angle 213 for incoupling of light from the light source 204 into the light guide 201. The light is collimated to enter the facet 210 in a direction parallel to the surface normal of the facet 210. As the angle 213 of the facet 210 corresponds to the TIR angle of the light, for example blue light, the full amount of light can be extracted by the diffraction grating 207. Likewise, the facets 211 and 212 have angles 214 and 215 for incoupling of light from the light sources 205 and 206 into the light guides 202 and 203, respectively. The configuration of the diffraction grating 207 may be different from the configuration of the diffraction gratings 208 and 209 of the light guides 202 and 203, respectively. The parameters of the gratings 207, 208, and 209 can consequently be different for each of the light sources 204, 205, and 206 for changing the diffraction efficiency of the wavelengths separately. In the embodiment in FIG. 2, red (R), green (G), and blue (B) light sources are presented. For instance, A for B can be chosen such that θ_{g}=θ_{c} for the smallest desired θₒᵤₜ. The period of the diffraction gratings for the other colors can then be chosen such that the same angular range is covered. For example, a constant efficiency for all colors may be obtained in the angular range −10°<θₒᵤₜ<10°, with respect to diffraction efficiencies, when optimizing the grating period for each wavelength, e.g. Λ=580 nm for R, Λ=488 nm for G and Λ=432 nm for B. There are several options to make the efficiencies equal, or within a range, for all colors; i.e. the grating depth and shape, the grating coverage and/or the light guide thickness can be varied. Changing the grating depth has effect on the—1^{st} order diffraction efficiencies. For instance, a thickness of 240 nm for the light guide 203 for R, 200 nm for the light guide 202 for G and 190 nm for the light guide 201 for B may give an diffraction efficiency of 0.25 for all three colors. In practice, other thicknesses for the light guides may be chosen to compensate for other effects, like the number of bounces that differs for the different colors. The above-mentioned options for influencing the outcoupling efficiency, grating depth and shape, grating coverage, and light guide thickness, may also be used to ensure a homogeneous light distribution over the surface area of the light guide. For this purpose, especially the grating coverage may be varied in both embodiments according to the above. In this case specific areas on the light guide may not be covered by a diffraction grating and the grating coverage is adapted such that a homogeneous illumination is obtained.

Another effect that may influence the intensities of the outcoupled light is the diffraction of the diffracted light by the other gratings. The order between the light guides 203, 202 and 201 for the colors R, G and B, respectively is optimal in the configuration of FIG. 2, in which case the middle (G) light guide 202 transmits 84% of R light and the upper (B) light guide 201 transmits 90% of R light and 79% of G light. All other arrangements may be less efficient.

A reflector 217 may be placed parallel to the light guides 201, 202, and 203. Light emitted in the direction of the reflector 217 will be reflected in the opposite direction. A diffraction grating 207, 208, 209, may cover one or both sides of each light guide.

The light guides 201, 202, and 203 are arranged parallel to each other. This will result in the most compact design of the device for mixing light 200, but other configurations of the light guides 201, 202, and 203 are also possible. The light guides 201, 202, and 203 are separated by a spacing 216, in which a medium of a suitable diffraction index is present, such as air, to achieve TIR in the aforementioned light guides.

FIG. 4 shows the light guides 201, 202 and their respective light incoupling facets, 210 and 211, in FIG. 2 from above. As illustrated in FIG. 4, the configuration of the light guides 201, 202, may be chosen such that the gratings make an angle 401 in the direction perpendicular to the plane of drawing in FIG. 2, such as an angle of 90° or 120°, for instance. The light guide 203 may also make an angle in relation to the other light guides 201, 202. An advantage of such a configuration may be that the device for mixing light can be made compact as the light sources for directing light to the facets, 210 and 211, can be placed further away from each other.

Although the present invention has been described in connection with particular embodiments thereof, it is to be understood that various modifications, alterations and adaptations may be made by those skilled in the art without departing from the claimed scope.

1. Device for mixing light comprising:
at least two light sources wherein a first light source emits light of a first wavelength and a second light source emits light of a second wavelength,
at least one light guide having a diffraction grating for outcoupling of light, characterized in that;
the at least one light guide comprise a facet for each of the at least two light sources for incoupling of light, whereby
a first facet is adapted to couple light of the first wavelength into the at least one light guide, and
second facet is adapted to couple light of the second wavelength into the at least one light guide.

2. Device for mixing light according to claim 1, wherein the first and second facet is mounted in an angle in relation to the at least one light guide, wherein
a first angle of the first facet corresponds to an angle for total internal reflection of the first wavelength in the at least one light guide,
a second angle of the second facet corresponds to an angle for total internal reflection of the second wavelength in the at least one light guide.

3. Device for mixing light according to claim 1, wherein the first and second light source emit light into separate light guides, such that a first light guide direct light of the first wavelength and a second light guide direct light of the second wavelength.

4. Device for mixing light according to claim 3, wherein the first and second light guides extend in two parallel planes, separated by an air spacing.

5. Device for mixing light according to claim 1, further comprising a third light source, wherein the first, second and third light source each emit wavelengths corresponding to any of red, green or blue light.

6. Device for mixing light according to claim 1, comprising a reflector positioned parallel to the at least one light guide.

7. Device for mixing light according to claim 3, wherein three light guides extend in three planes parallel to each other, further comprising a reflector positioned parallel to the light guides, said reflector being closest to the third light guide, the third light guide directs red light, the second light guide directs green light, the first light guide directs blue light, wherein the second light guide is positioned between the first and third light guide.

8. Device for mixing light according to claim 1, wherein a thickness of the at least one light guide, a diffraction grating period, or a diffraction grating depth or any combination thereof is adapted such that the efficiency of light outcoupling is within a range for all wavelengths.

9. Device for mixing light according to claim 1, wherein the light of the first wavelength is collimated to enter the first facet parallel to the surface normal of the first facet, and the light of the second wavelength is collimated to enter the second facet parallel to the surface normal of the second facet.

10. Device for mixing light according to claim 3, wherein the diffraction grating of the first light guide defines an off-set angle with respect to the diffraction grating of the second light guide.

11. Device for mixing light according to claim 1, wherein the diffraction grating covers at least one light outcoupling surface of the at least one light guide.

12. Device for mixing light according to claim 1, wherein the at least two light sources are LEDs.

13. Device for mixing light according to claim 1, wherein the light outcoupled by the diffraction grating is white.
